(19) United States
(12) Patent Application Publication
(10) Pub. No.: US 2012/0015799 A1
(43) Pub. Date: Jan. 19, 2012

(54) METHOD FOR PRODUCING SAPPHIRE SINGLE CRYSTAL, AND SAPPHIRE SINGLE CRYSTAL OBTAINED BY THE METHOD

(75) Inventor: Tomohiro Shonai, Chiba (JP)

(73) Assignee: SHOWA DENKO K.K., Tokyo (JP)

(21) Appl. No.: 13/258,419

(22) PCT Filed: Jun. 25, 2010
(86) PCT No.: PCT/JP2010/060810

§ 371 Date: Sep. 21, 2011

(30) Foreign Application Priority Data
Jul. 3, 2009 (JP) 2009-158444

(51) Int. Cl. C30B 29/20; F24J 3/00; B28D 5/00; C30B 15/00

(52) U.S. Cl. 501/86; 117/13; 432/1; 125/30.01

(57) ABSTRACT

A method for producing a sapphire single crystal, which includes: performing a sapphire single crystal growth step wherein a sapphire ingot, which is an ingot of sapphire single crystal, is produced (step 101); performing a subsequent ingot heating step wherein the sapphire ingot obtained in the sapphire single crystal growth step is heated (step 102); and performing a subsequent ingot processing step wherein the heated sapphire ingot is machined (step 103). In the ingot heating step, the sapphire ingot is heated in an atmosphere in which the oxygen concentration is increased to be equal to or higher than that in the air. Consequently, crystal defects in the ingot of sapphire single crystal produced by crystal growth are removed and the occurrence of cracks in the sapphire ingot during machining of the sapphire ingot is suppressed, thereby improving the yield of sapphire products obtained from the ingot.

### TECHNICAL FIELD

The present invention relates to a method for producing a sapphire single crystal, and a sapphire single crystal obtained by the method.

### BACKGROUND ART

In recent years, a sapphire single crystal is widely used as a substrate material for growing an epitaxial film of a group III nitride semiconductor (such as GaN) on the occasion of producing blue LEDs, for example. Additionally, a sapphire single crystal is also widely used as a holding member or the like of a light polarizer used for a liquid crystal projector, for example.

In general, a plate member, namely, a wafer of such sapphire single crystal is obtained by cutting an ingot of sapphire single crystal to have a predetermined thickness. Various methods to produce ingots of sapphire single crystal have been proposed; however, a melting and solidifying method is often employed in the production, because this method provides favorable crystal characteristics and is likely to provide crystals having large diameters. In particular, the Czochralski method (Cz method), which is one of melting and solidifying methods is widely used.

To produce ingots of sapphire single crystal by using the Czochralski method, a crucible is first filled with a material of aluminum oxide and is heated by using a high-frequency induction heating method or a resistance heating method, to thereby melt the material. After the material is melt, a seed crystal having been cut along a predetermined crystal orientation is brought into contact with the surface of the melt of the material. The seed crystal is pulled upward at a predetermined speed while being rotated at a predetermined rotation speed, to thereby grow a single crystal (refer to Patent Document 1, for example).

### CITATION LIST

### Patent Literature

Patent Document 1: Japanese Patent Application Laid-Open Publication No. 2008-207992

### SUMMARY OF INVENTION

### Technical Problem

Incidentally, a part of an ingot of sapphire single crystal developed by crystal growth is left as it is to be used as a product, and the other part is subjected to machine processing such as cutting. Further, for example, in the case of obtaining a plate-like sapphire substrate from an ingot of sapphire single crystal, the ingot of sapphire single crystal is subjected to cutting (slicing) to be divided into plural plate-like sapphire single crystals. Here, at the time of performing machine processing as described above on an ingot of sapphire single crystal, if crystal strain is generated in the ingot of sapphire single crystal to be processed, damage such as cracks or the like is likely to occur in the ingot of sapphire single crystal. Ordinarily, in the case of occurrence of damage such as cracks or the like in an ingot of sapphire single crystal, a part in which cracks occur is discarded and the remaining part is used as a product.

The crystal strain due to a thermal stress in a single crystal producing step is likely to occur in ingots of sapphire single crystal produced by many melting and solidifying methods, and there was a problem of easily causing damage such as cracks in the ingot of sapphire single crystal on the occasion of performing subsequent machine processing.

An object of the present invention is to facilitate removal of crystal strain in an ingot of sapphire single crystal produced by crystal growth, thereby stably improving the yield of sapphire products obtained from the ingot of sapphire single crystal.

### Solution to Problem

In order to attain the object, there is provided a method for producing a sapphire single crystal to which the present invention is applied, including: a first step in which an ingot of sapphire single crystal to be subjected to machine processing is mounted in a heating apparatus for heating the ingot of sapphire single crystal; and a second step in which the ingot of sapphire single crystal mounted in the heating apparatus is heated in an atmosphere containing at least one kind selected from a group composed of helium, neon, argon, nitrogen, oxygen, carbon dioxide and carbon monoxide.

In such a method for producing a sapphire single crystal, the atmosphere in the second step may contain at least oxygen. In this case, the second step may be performed in the atmosphere in which oxygen concentration is increased to be equal to or more than oxygen concentration in the air.

Further, other than oxygen, at least one kind selected from a group composed of helium, neon, argon, nitrogen, carbon dioxide and carbon monoxide may be used.

In the present invention, an atmosphere gas, which is a mixture of oxygen and nitrogen containing oxygen to show oxygen concentration of 21 volume percent (the air) or more, may be preferably used in terms of production cost.

Further, in such a method for producing a sapphire single crystal, the oxygen concentration of the atmosphere in the second step may be equal to or more than 23 volume percent. Moreover, the atmosphere in the second step may be heated to a range of 1500° C. or more to less than 1800° C. The second step may be continued for more than 30 hours.

Still further, in the first step, the ingot of sapphire single crystal to be subjected to machine processing for obtaining at least two plate-like sapphire single crystals may be used. Moreover, in the first step, the ingot of sapphire single crystal having been obtained by a pulling method may be used.

From another viewpoint, the present invention may provide a method of producing a sapphire single crystal, in which machine processing is further applied to the ingot of sapphire single crystal obtained by the above-described method of producing a sapphire single crystal to produce a sapphire single crystal.

### Advantageous Effects of Invention

According to the present invention, it is possible to facilitate to remove the crystal strain in an ingot of sapphire single crystal produced by crystal growth, thereby making it possible to stably improve the yield of sapphire products obtained from the ingot of sapphire single crystal. In particular, it becomes possible to stably improve the yield of sapphire products obtained from the ingot of sapphire single crystal having a large diameter of 4 inches or more. Further, in a method of producing by pulling a c-axis sapphire single crystal having a large diameter of 4 inches or more, the yield may be significantly improved.

### BRIEF DESCRIPTION OF DRAWINGS

FIG. 1 is a flowchart for illustrating an example of producing procedures of a sapphire ingot in the exemplary embodiment;

FIG. 2 is a diagram of an example for illustrating a configuration of a single crystal pulling apparatus;

FIGS. 3A to 3D are diagrams of an example for illustrating an ingot processing step;

FIG. 4 is a diagram of an example for illustrating an entire configuration of a heating apparatus;

FIG. 5 is a diagram of an example for illustrating an ingot heating step in the exemplary embodiment;

FIG. 6 is a diagram of an example for illustrating an atmosphere condition at the time of heating;

FIG. 7 is a diagram of an example for illustrating a condition of a maintained temperature; and

FIG. 8 is a diagram of an example for illustrating a condition of a maintaining time.

### DESCRIPTION OF EMBODIMENTS

An exemplary embodiment of the present invention will be described in detail below with reference to the accompanying drawings.

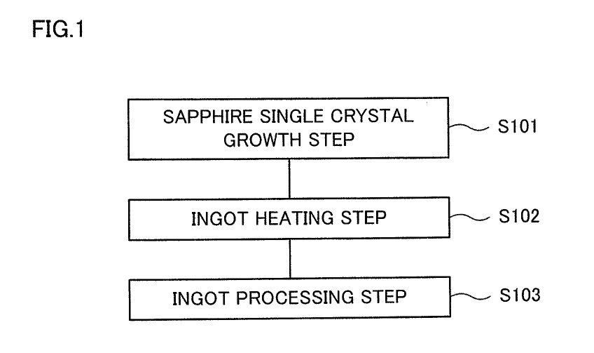

FIG. 1 is a flowchart for illustrating an example of producing procedures of a sapphire ingot in the exemplary embodiment.

In the exemplary embodiment, as shown in FIG. 1, “sapphire single crystal growth step” in which crystal growth of a sapphire single crystal is carried out to prepare an ingot of sapphire single crystal (hereinafter, referred to as a sapphire ingot 10) is performed (step 101). Next, “ingot heating step” in which the sapphire ingot 10 obtained in the sapphire single crystal growth step is subjected to heating treatment is performed (step 102). Thereafter, “ingot processing step” in which machine processing is applied to the sapphire ingot 10 having been subjected to the heating treatment is performed (step 103).

### <Sapphire Single Crystal Growth Step>

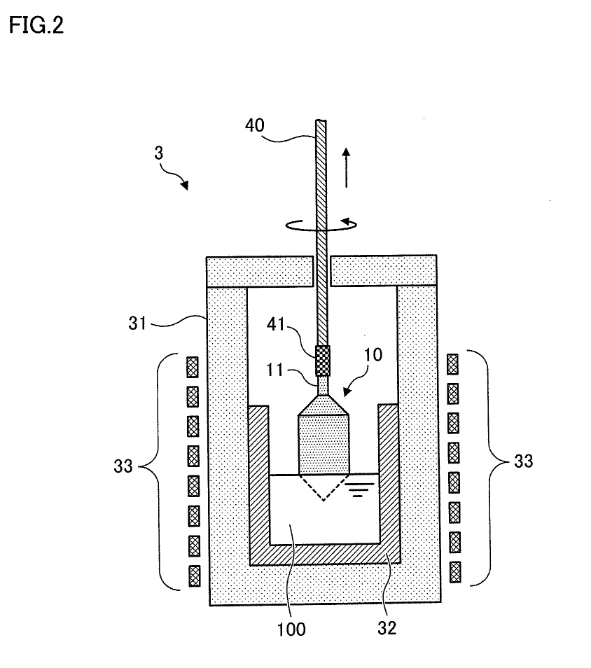

FIG. 2 is a diagram of an example for illustrating a configuration of a single crystal pulling apparatus 3.

The single crystal pulling apparatus 3 shown in FIG. 2 is used in the sapphire single crystal growth step. The single crystal pulling apparatus 3 in the exemplary embodiment performs growth of a sapphire single crystal by the Czochralski (Cz) method, which is one of the melting and solidifying methods. As shown in FIG. 2, the single crystal pulling apparatus 3 according to the exemplary embodiment includes: a heat insulated container 31; a crucible 32; a heating coil 33; a pulling bar 40; and a seed crystal holder 41.

The heat insulated container 31 has a cylindrical outer shape, and has a cylindrical space formed therein. The heat insulated container 31 is composed by assembling components formed of a heat insulating material made of zirconia. The crucible 32 is provided at a lower portion inside of the heat insulated container 31 and contains an aluminum melt 100 made by melting aluminum oxide. The crucible 32 is arranged so as to open vertically upward, as shown in FIG. 2.

The heating coil 33 is arranged so as to face a wall surface of the crucible 32 with the heat insulated container 11 interposed therebetween. The lower edge portion of the heating coil 33 is located lower than the lower edge of the crucible 32, while the upper edge portion of the heating coil 33 is located higher than the upper edge of the crucible 32.

When a high-frequency current is supplied, the heating coil 33 generates an eddy current in the crucible 32. Then, in the crucible 32, Joule heat is generated to thereby heat the crucible 32. When, as the crucible 32 is heated, the aluminum oxide contained in the crucible 32 is heated to a temperature higher than the melting point thereof (about 2050° C.), the aluminum oxide is melted in the crucible 32 to provide the aluminum melt 100.

The pulling bar 40 extends downward from above the heat insulated container 31. The pulling bar 40 is configured with a metal bar of, for example, stainless steel, and is attached so as to be movable in a vertical direction and rotatable around an axis. Additionally, the seed crystal holder 41 for mounting a seed crystal 11, which will be described later, is attached to the side of the pulling bar 40 facing the crucible 32.

The pulling bar 40 is connected to a pulling drive unit (not shown) for pulling the pulling bar 40 vertically upward and a rotation drive unit (not shown) for rotating the pulling bar 40. The pulling drive unit is configured with a motor so as to be capable of adjusting a pulling speed of the pulling bar 40. The rotation drive unit is also configured with a motor so as to be capable of adjusting a rotation speed of the pulling bar 40.

To grow a sapphire single crystal by the single crystal pulling apparatus 3 as configured above, first, a material of aluminum oxide is charged into the crucible 32. Then the crucible 32 is subjected to induction heating by passing electric current through the heating coil 33 to melt aluminum oxide in the crucible 32, and thereby the crucible 32 is filled with aluminum melt. Thereafter, the seed crystal 11 composed of a sapphire single crystal is brought into contact with the aluminum melt in the crucible 32, and the seed crystal 11 is pulled upward while being rotated to successively grow a sapphire single crystal on the seed crystal 11. It should be noted that, in the exemplary embodiment, the sapphire ingot 10 is grown in size such that the length in the pulling direction is about 30 cm, and the maximum diameter (width of cross section orthogonal to the pulling direction) is over 10 cm. In the exemplary embodiment, the sapphire ingot 10 can also be grown in size such that the length in the pulling direction is about 30 cm or more, and the maximum diameter is over 10 cm or more. The sapphire single crystal growth step is completed by taking out the sapphire ingot 10, namely, a sapphire single crystal having been grown, and by cooling thereof.

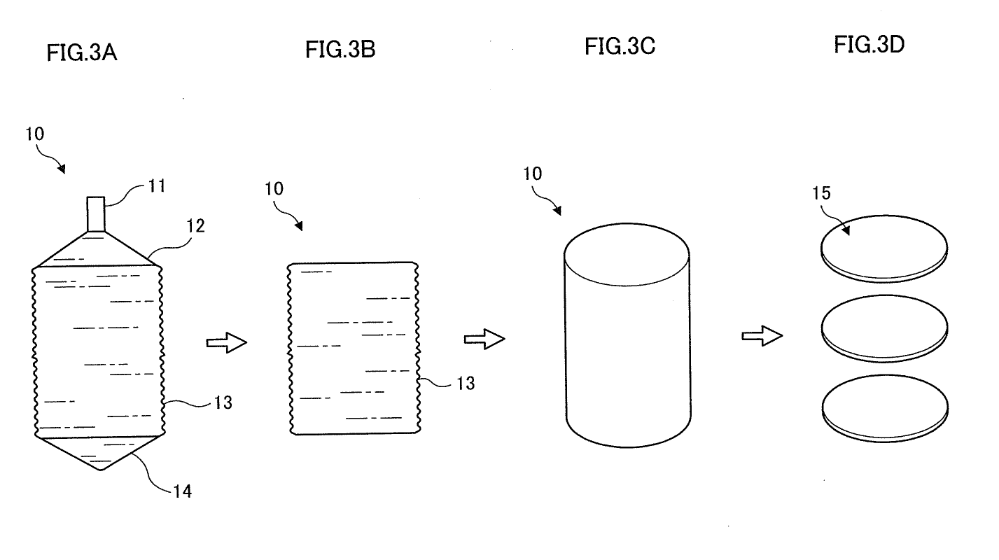

It should be noted that the sapphire ingot 10 after production includes: a shoulder portion 12 formed in an early stage of crystal growth; a body portion 13 formed as a portion to be used as a product; and a tail portion 14 formed on an opposite side of the shoulder portion 12 (refer to FIG. 3A, which will be described later).

### <Ingot Heating Step>

The ingot heating step applies heating treatment to the sapphire ingot 10 obtained in the above-described sapphire single crystal growth step. The ingot heating step facilitates removal of the crystal strain in the sapphire ingot 10. By applying heating treatment to the sapphire ingot 10 to remove the crystal strain in this manner, for example, damage to the sapphire ingot 10 due to an impact in machine processing in executing the later-described ingot processing step can be suppressed. It should be noted that the ingot heating step will be described in detail later.

### <Ingot Processing Step>

FIGS. 3A to 3D are diagrams of an example for illustrating an ingot processing step.

The ingot processing step applies machine processing to the sapphire ingot 10 having undergone the ingot heating step. Specifically, as shown in FIGS. 3A and 313, the shoulder portion 12 and the tail portion 14 are cut from the sapphire ingot 10 by use of an inner diameter blade cutting machine or the like while leaving the body portion 13 to be used as a product. Thereafter, as shown in FIG. 3C, circumferential grinding is applied to the body portion 13 so as to cut off asperities formed on the side surface of the sapphire ingot 10.

The sapphire ingot 10 is further processed into a desired shape to be used as products such as substrates of semiconductor devices and machine parts. For example, by cutting the sapphire ingot 10 in a direction orthogonal to the pulling direction thereof (longitudinal direction of the sapphire ingot 10 shown in FIG. 3C), sapphire wafers 15, which are plate-like sapphire single crystals as shown in FIG. 3D, can be obtained. It should be noted that, in the exemplary embodiment, since crystal growth of the sapphire ingot 10 is performed in the c-axis direction, the principal face of the obtained sapphire ingot 10 is a c-face ((0001) face). Then, for instance, if the sapphire wafer 15 is used as a substrate of a blue LED (light emitting diode), a semiconductor film such as AlN film, GaN film, InGaN film and the like is appropriately formed on the sapphire wafer 15.

Subsequently, the ingot heating step (a temperature rising step, a temperature maintaining step and a temperature falling step) will be described in detail. It should be noted that, in the exemplary embodiment, the heating step is executed mainly in an atmosphere containing at least one kind selected from a group composed of nitrogen and oxygen.

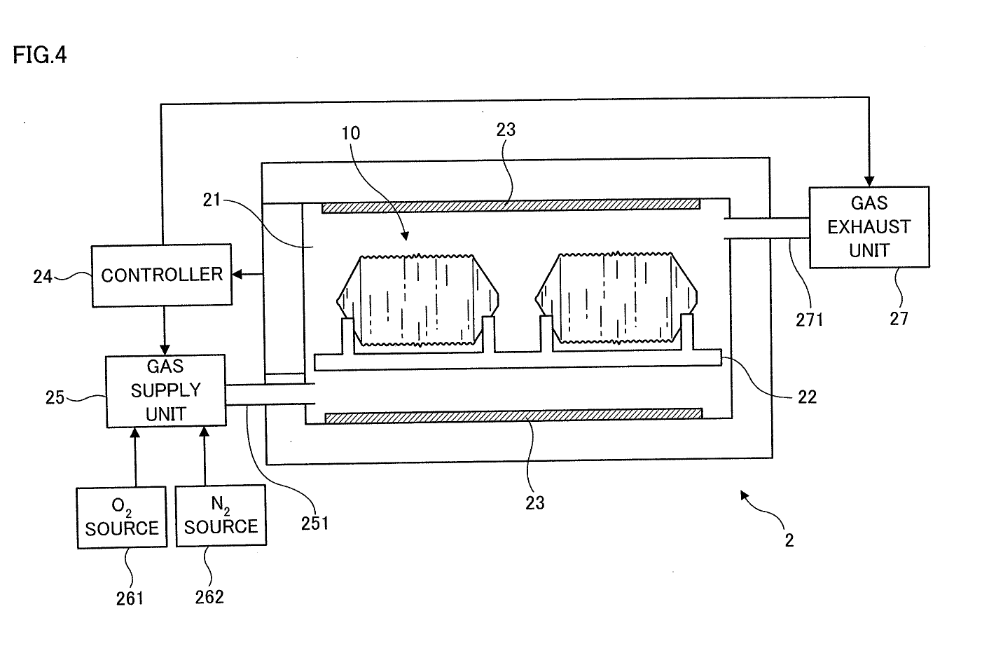

FIG. 4 is a diagram of an example for illustrating an entire configuration of a heating apparatus 2.

The heating apparatus 2 shown in FIG. 4 is used to heat the sapphire ingot 10 in the ingot heating step. The heating apparatus 2 includes, as shown in FIG. 4: a furnace chamber 21, a mounting base 22 on which the sapphire ingot 10 is mounted; a heater 23 which is a heat source; a controller 24 that controls heating temperature of the heater 23 or the like; a gas supply unit 25 that supplies an atmosphere gas containing, for example, a nitrogen gas and an oxygen gas to the inside of the furnace chamber 21; and a gas exhaust unit 27 that exhausts the atmosphere gas from the inside of the furnace chamber 21.

It should be noted that the gas supply unit 25 of the exemplary embodiment is capable of preparing an atmosphere gas containing at least one kind selected from a group composed of helium, neon, argon, nitrogen, oxygen, carbon dioxide and carbon monoxide, and supplying the gas to the inside of the furnace chamber 21.

The mounting base 22 in the exemplary embodiment is a base for mounting the sapphire ingot 10. In the exemplary embodiment, the mounting base 22 is made of aluminum oxide, which is akin to the sapphire ingot 10, since the sapphire ingot 10 is to be heated. Consequently, adhesion of foreign substances other than aluminum oxide to the sapphire ingot 10 is prevented when the sapphire ingot 10 is heated. For example, if the mounting base 22 is configured with a material other than aluminum oxide, there is a possibility that the material of the mounting base 22 reacts with the sapphire ingot 10, or the material reacts with the atmosphere gas, thereby resulting in adhesion of foreign substances to the sapphire ingot 10. As a consequence, in the exemplary embodiment, the mounting base 22 is made of aluminum oxide, which is akin to the sapphire ingot 10.

Further, by making the mounting base 22 with a material similar to that of the sapphire ingot 10, their thermal conductivities become equal. In this way, the exemplary embodiment is configured so that, for example, temperature rise or temperature drop in the part of the sapphire ingot 10, which is in contact with the mounting base 22, compared to the other part thereof is suppressed so that the sapphire ingot 10 is uniformly heated.

The gas supply unit 25 supplies the inside of the furnace chamber 21 with the atmosphere gas through a gas supply pipe 251. In the exemplary embodiment, the gas supply unit 25 is capable of supplying, for example, a mixed gas that is a mixture of oxygen supplied from an O₂ source 261 and nitrogen as an example of an inert gas supplied from an N₂ source 262. The gas supply unit 25 is capable of adjusting the concentration of the oxygen in the mixed gas by making a mixture ratio of the oxygen and the nitrogen being variable, and is also capable of adjusting a flow rate of the mixed gas supplied to the inside of the furnace chamber 21.

The gas exhaust unit 27 exhausts the atmosphere gas from the inside of the furnace chamber 21 through the gas exhaust pipe 271. The gas exhaust unit 27 is configured with, for example, a pump, and is capable of adjusting a flow rate of the atmosphere gas exhausted from the inside of the furnace chamber 21.

The heater 23 heats the atmosphere gas in the furnace chamber 21, and heats the sapphire ingot 10 through the atmosphere gas. As the heater 23 in the exemplary embodiment, a ceramic heater is employed. Any kind of heat sources may be suitably used as the heater 23. However, in the exemplary embodiment, sapphire ingot 10 is heated while setting the oxygen concentration in the atmosphere gas in the furnace chamber 21 to be equal to or more than that in the air, as will be described later. As a consequence, the ceramic heater is used in the exemplary embodiment, which is hardly affected such as being deteriorated even in the high oxygen content atmosphere.

The controller 24 receives settings such as maintained temperature T1, maintaining time t in heating, temperature rising rate (rising temperature per unit time), temperature falling rate (falling temperature per unit time) and the like, which will be described later, and controls the temperature in the furnace chamber 21 or the heating temperature of the heater 23 based on the temperature of the sapphire ingot 10 or the like. The controller 24 further adjusts the amount of gas supplied by the gas supply unit 25 or the amount of gas exhausted by the gas exhaust unit 27 to set the oxygen concentration in the furnace chamber 21 to a predetermined condition.

It should be noted that, though not shown, the heating apparatus 2 is suitably provided with a thermometer to measure the temperature of the atmosphere gas in the furnace chamber 21 and an oxygen concentration detector to measure the oxygen concentration in the atmosphere gas in the furnace chamber 21. Further, the heating apparatus 2 may be configured to include a temperature detector to measure the temperature of the sapphire ingot 10 itself, thus directly detecting the temperature of the sapphire ingot 10.

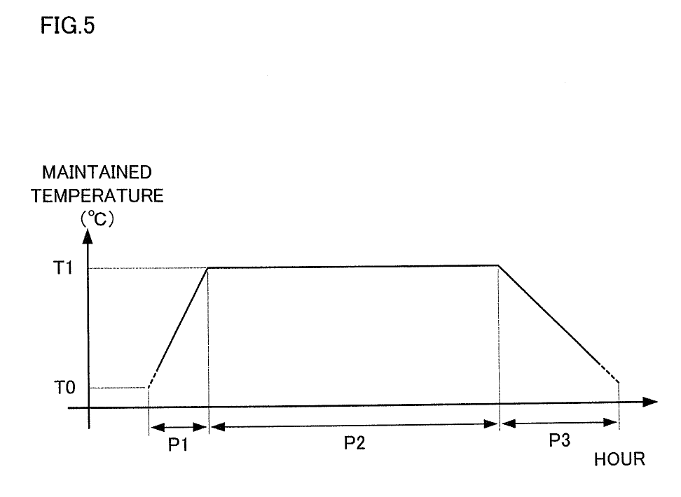

FIG. 5 is a diagram of an example for illustrating the ingot heating step in the exemplary embodiment.

First, as described with reference to FIG. 4, the sapphire ingot 10 is mounted on the mounting base 22 provided in the furnace chamber 21 in the heating apparatus 2 (first step). Then, as will be described below, the sapphire ingot 10 is subjected to heating treatment by undergoing a temperature rising step P1 in which temperature rises, a temperature maintaining step P2 in which a predetermined temperature is maintained for a given length of time, and a temperature falling step P3 in which temperature falls (second step).

It should be noted that, in the following description, the temperature maintained in the temperature maintaining step P2 is referred to as “maintained temperature T1” and the time for maintaining the temperature of the sapphire ingot 10 at the maintained temperature T1 is referred to as “maintaining time t”.

### (Temperature Rising Step)

In the first place, the gas supply unit 25 and the gas exhaust unit 27 are adjusted, thereby adjusting the atmosphere condition in the furnace chamber 21 so that the oxygen concentration in the atmosphere gas in the furnace chamber 21 becomes, for example, concentration of 21 volume percent (the air level) or more. Then, by starting to heat by the heater 23, the heater 23 is controlled to change the temperature of the atmosphere gas in the furnace chamber 21 from an initial temperature T0 (for example, 25° C., the room temperature) to the maintained temperature T1, as shown in FIG. 5. It should be noted that, in the exemplary embodiment, the maintained temperature T1 is set to 1600° C., for example. Further, in the exemplary embodiment, the atmosphere condition in the furnace chamber 21 at the time of heating is set to be equal to or more than the oxygen concentration in the air (21 volume percent).

It should be noted that, the time for rising from the initial temperature T0 to the maintained temperature T1 is set based on a temperature rising rate, for example, though the time is also dependent on the atmosphere condition. In the exemplary embodiment, for example, the temperature rising rate is assumed to be 2° C./minute. In the present invention, the temperature rising rate is also dependent on the atmosphere condition and is not particularly limited, but ordinarily, the temperature rising rate is preferably set arbitrarily within the range of 0.5° C./minute or more to less than 50° C./minute, and more preferably, set within the range of 1° C./minute or more to less than 5° C./minute. Further, if the lower limit is set to 0.5° C./minute or less, the time required by the step becomes longer, and thereby productivity is decreased and impracticality also occurs in terms of cost. In the case of the rate exceeding 50° C./minute, large temperature gradient occurs in the sapphire ingot 10, and thermal stress is generated.

Moreover, in the temperature rising step P1, the temperature may rise from the initial temperature T0 to the maintained temperature T1 in one step, or may rise from the initial temperature T0 to the maintained temperature T1 through plural steps including plural temperature rising steps.

### (Temperature Maintaining Step)

In the temperature maintaining step P2, the temperature of the atmosphere gas is maintained at the maintained temperature T1. In the exemplary embodiment, the maintained temperature T1 is assumed to be 1600° C., for example. Further, while the temperature in the furnace chamber 21 is controlled to be maintained at the maintained temperature T1, the temperature maintaining step P2 is continued for 50 hours. It should be noted that it is preferable to set the maintained temperature T1 within the range of 1500° C. or more to less than 1800° C. Further, the maintaining time t is preferably set to, for example, 30 hours or more.

### (Temperature Falling Step)

In the temperature falling step P3, after a lapse of the maintaining time t in the temperature maintaining step P2, the temperature of the sapphire ingot 10 is decreased from the maintained temperature T1. It should be noted that, in the present invention, the temperature falling rate is not particularly limited, but it is desirable to set the temperature falling rate within the range of 0.5° C./minute or more to less than 2° C./minute.

Incidentally, the reason why the magnitude relation between the temperature rising rate and the temperature falling rate is set as described above is that, if these rates are too large, there is a possibility of occurrence of cracks in the sapphire ingot 10 by thermal shock, and in particular, since the thermal shock is apt to be caused at the time of temperature falling, it is preferable to set the temperature falling rate smaller than the temperature rising rate. Further, in the temperature rising step and the temperature falling step, if the lower limit is set to 0.5° C./minute or less, the time required by these steps becomes longer, and thereby productivity is decreased and impracticality also occurs in terms of cost.

Next, the heating conditions in the above-mentioned heating step of the sapphire ingot 10 will be described in detail.

Hereinafter, examples of a preferable condition of the oxygen concentration in the atmosphere gas, the maintained temperature T1 and the maintaining time t in the heating step of the sapphire ingot 10 are provided.

The present inventors performed the ingot heating step by use of the sapphire ingot 10 that has undergone the sapphire single crystal growth step with the atmosphere condition, maintained temperature T1 and maintaining time t being varied. As a consequence, plural sapphire ingots 10 prepared under the respective conditions were obtained. Thereafter, similar to the ingot processing step, process of cutting the shoulder portion 12 and the tail portion 14 was performed on the samples of obtained plural sapphire ingots 10. Then, four-grade evaluations (evaluation A, evaluation B, evaluation C and evaluation D) were performed based on the ratio of occurrence of cracks by cutting.

Here, evaluation A represents that the incidence of cracks was less than 10%.

Evaluation B represents that the incidence of cracks was 10% or more to less than 40%.

Evaluation C represents that the incidence of cracks was 40% or more to less than 70%.

Evaluation D represents that the incidence of cracks was 70% or more.

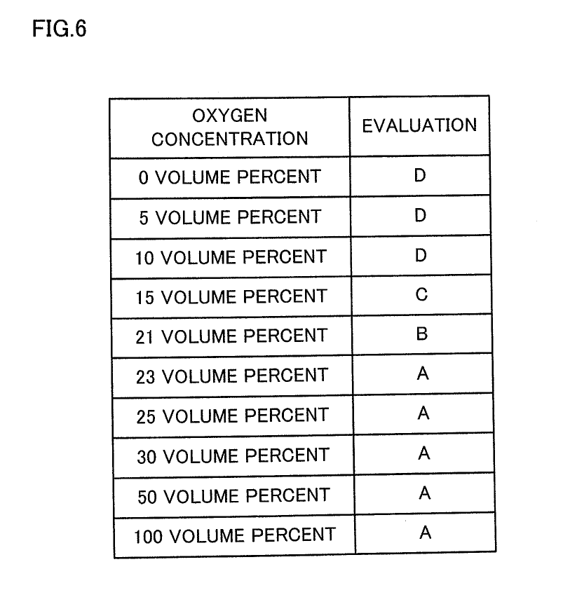

FIG. 6 is a diagram of an example for illustrating the atmosphere condition at the time of heating.

In the ingot heating step, plural sapphire ingots 10 were prepared with the condition of the atmosphere in heating (the atmosphere in the furnace chamber 21 in the heating apparatus 2) being varied, and the sapphire ingots 10 obtained under the respective conditions were evaluated. It should be noted that, in the example shown in FIG. 6, the maintained temperature T1 is set to 1600° C. and the maintaining time t is set to 50 hours.

As shown in FIG. 6, in the cases where the oxygen concentration is 0 volume percent, 5 volume percent and 10 volume percent, the evaluations were D. In the cases where the ingot heating step was performed with the oxygen concentration being set in the above-described ranges, the cracks occurred in a large number of samples. It is understood that, under the above-described condition of the oxygen concentration, the oxygen concentration is insufficient to remove the crystal strain occurred in the sapphire ingot 10.

Next, in the case where the oxygen concentration was set to 15 volume percent, the evaluation was C. It was learned that the incidence of cracks could be suppressed to some extent by setting the oxygen concentration to 15 volume percent. However, since the cracks occurred in more than about half of the samples, it was understood that the oxygen concentration is insufficient to remove the crystal strain even under this condition of the oxygen concentration.

Then, in the case where the oxygen concentration was set to 21 volume percent, the evaluation was B. In other words, in the case where the oxygen concentration was set to 21 volume percent, which is the same as that of the air atmosphere, the incidence of cracks was significantly declined compared to the cases of setting of the above-described oxygen concentrations. Further, the aforementioned tendencies indicate that the incidence of cracks gradually decreases with the increase of the oxygen concentration; therefore, it can be seen that the higher the oxygen concentration, the more the removal rate of the crystal strain is improved.

In the cases where the oxygen concentration was set to 23 volume percent and 25 volume percent, the evaluations were A. In other words, it was found out that, in the case where the oxygen concentration was set to 23 volume percent, which is higher than that of the air atmosphere, the cracks hardly occur compared to the cases of setting of the above-described oxygen concentrations. This is thought to be because the crystal strain was removed by movement of atoms due to intrusion of oxygen of the atmosphere gas into oxygen deficiencies having occurred inside the sapphire ingot 10. Note that the intrusion of oxygen is thought to have been caused by heating the sapphire ingot 10 with the oxygen concentration higher than that of the air atmosphere. It is thought, as a result thereof, the cracks hardly occur even though an impact such as performing machine processing is posed to the sapphire ingot 10.

Moreover, in the cases where the oxygen concentration was set to 30 volume percent, 50 volume percent and 100 volume percent, it was also confirmed that evaluation results were A. Here, it was confirmed that, when the oxygen concentration exceeds 50 volume percent and becomes still higher, the incidence of cracks is further decreased. However, in the cases where the oxygen concentrations were 50 volume percent and 100 volume percent, there was not much difference in the incidence of the cracks therebetween. It should be noted that, the oxygen concentration of the atmosphere at the time of heating may be at least 21 volume percent, and more preferably, the oxygen concentration may be 50 volume percent or less with the view to cost and effect of removal of the crystal strain.

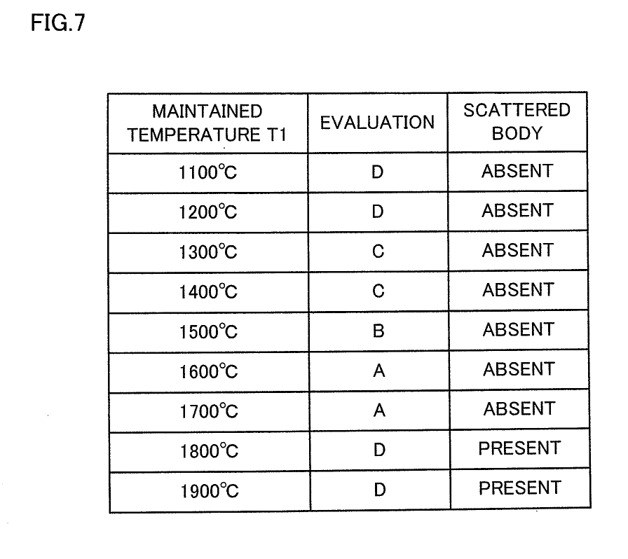

FIG. 7 is a diagram of an example for illustrating a condition of the maintained temperature T1.

In the ingot heating step, plural sapphire ingots 10 were prepared with the condition of the maintained temperature T1 being varied, and each of them was evaluated. It should be noted that, in the example shown in FIG. 7, the oxygen concentration in the atmosphere condition is set to 23 volume percent, and the maintaining time t is set to 50 hours. Further, in FIG. 7, presence or absence of scattered bodies that are possibly generated with the increase of the heating temperature of the sapphire ingot 10 is also indicated. The scattered bodies represent a phenomenon, which is seen due to occurrence of defects inside the crystal, and can be confirmed by visual observation with, for example, inspection under light-gathering illumination.

First, as shown in FIG. 7, in the cases where the maintained temperature T1 was set to 1100° C. and 1200° C., evaluations thereof were D. It was learned that, if the maintained temperature T1 is in these temperature ranges, it is difficult to perform removal of the crystal strain, which is sufficient to suppress the occurrence of the cracks.

In the cases where the maintained temperature T1 was set to 1300° C. and 1400° C., evaluations thereof were C. It was learned that the incidence of cracks can be suppressed to some extent by setting the maintained temperature T1 to 1300° C. or more. However, though the maintained temperature T1 was in these temperature ranges, the cracks occurred in more than about half of the samples.

In the case where the maintained temperature T1 was set to 1500° C., evaluation thereof was B. It was understood that the crystal strain can be removed in a large number of sapphire ingots 10 by setting the maintained temperature T1 to this temperature range. This is assumed that the crystal strain was relieved since the atoms composing the sapphire ingot 10 were facilitated to move inside the sapphire ingot 10 due to setting the maintained temperature T1 to 1500° C. or more.

Then, in the cases where the maintained temperature T1 was set to 1600° C. and 1700° C., evaluations thereof were A. It is considered that the crystal was facilitated to move by setting the maintained temperature T1 to these temperature ranges, and thereby the crystal strain was relieved. Further, it is understood that external oxygen atoms were facilitated to enter into depths inside the sapphire ingot 10, and as a result, the crystal strain in the sapphire ingot 10 was removed, and thereby the incidence of cracks could be suppressed to an extremely low level.

It was found that, in the cases where the maintained temperature T1 was set to 1800° C. and 1900° C., the incidence of cracks became considerably high. Here, upon inspecting the obtained sapphire ingots 10, occurrence of scattered bodies in the sapphire ingots 10 was confirmed. Based on the aforementioned tendencies, it is thought that the higher the maintained temperature T1, the more the crystal strain is removed; however, in the case where the maintained temperature T1 is 1800° C. or more, it was found that crystal defects occur in the sapphire ingots 10 due to heating, conversely.

It should be noted that, since the melting point of the sapphire single crystal is about 2050° C., it is required to set the maintained temperature T1 to be at least lower than the melting point of sapphire.

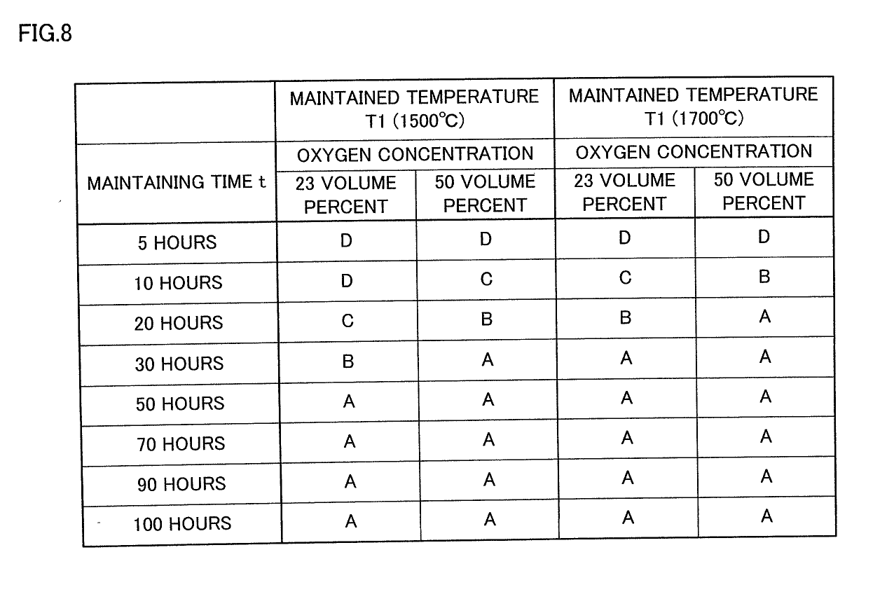

FIG. 8 is a diagram of an example for illustrating a condition of the maintaining time t.

In the ingot heating step, plural sapphire ingots 10 were prepared with the condition of maintaining time t being varied, and the sapphire ingots 10 obtained under the respective conditions were evaluated. Here, description will be made by taking the preferable condition of the oxygen concentration of the atmosphere gas (23 volume percent, 50 volume percent) and the maintained temperature T1 (1500° C., 1700° C.) as examples, as described with reference to FIGS. 6 and 7.

As shown in FIG. 8, it became apparent that the longer the maintaining time t, the lower the incidence of cracks becomes. Further, it was found that, even in the same maintaining time t, the higher the oxygen concentration, the better the evaluation becomes; and the higher the maintained temperature T1, the better the evaluation becomes. For example, it is found that, in the case where the maintained temperature T1 was 1700° C. and the oxygen concentration was set to 50 volume percent, the evaluation thereof became B though the maintaining time t was set to 10 hours. Upon focusing attention on the oxygen concentration, in the case where the oxygen concentration was set to 50 volume percent, evaluation A and evaluation B were obtained by setting the maintaining time t to 20 hours.

From the results shown in FIG. 8, it is understood that, within the range of the maintained temperature T1 of 1500° C. or more to 1700° C. or less, if the maintaining time t is set to 30 hours or more, evaluation A or evaluation B is obtained, thus greatly reducing the incidence of the cracks.

It should be noted that, in the case where the maintaining time t is set to 70 hours, 90 hours and 100 hours, evaluation becomes A, however, no much difference is seen in the incidence of the cracks in the sapphire ingots 10 heated for these maintaining times t. From the above, the maintaining time t is preferably set to at least 30 hours, and in consideration of the time taken for the ingot heating step, cost, and the extent of the incidence of the cracks, the maintaining time t is more preferably set to 50 to 60 hours.

As described so far, in the exemplary embodiment, the heating conditions in the ingot heating step are set as follows: as for the atmosphere condition, the oxygen concentration is equal to or more than that in the air (21 volume percent); the maintained temperature T1 is within the range of 1500° C. or more to less than 1800° C.; and the maintaining time t is at least 30 hours, thus removing the crystal strain in sapphire ingot 10, and further suppressing occurrence of the cracks even though machine processing is applied afterward.

Here, as described with reference to FIG. 2, in the exemplary embodiment, production of sapphire ingot 10, which is an ingot of sapphire single crystal, having a maximum diameter of over 10 cm or more (4 inches or more) is performed by the Czochralski method, which is an example of the pulling methods. In the case of growth of sapphire single crystal by using the pulling method, it is known that strain is apt to occur in the crystal. It is also known that, in the pulling method, the crystal strain is more likely to occur if the crystal growth is performed in the c-axis direction in the crystal orientation of sapphire single crystal.

In contrast, in the exemplary embodiment, the ingot heating step is applied to the sapphire ingot 10 prior to the ingot processing step. As a consequence, the crystal strain in the sapphire ingot 10 can be effectively removed particularly in the case of producing the sapphire ingot 10 by use of the pulling method in which the crystal strain is apt to occur. Especially, the crystal strain in the sapphire ingot 10 having a maximum diameter of 4 inches or more can be effectively removed.

It should be noted that, as shown in FIG. 5, an example of heating of the ingot is presented in the temperature maintaining step P2 in the ingot heating step in such a way that the maintained temperature T1 is kept constant, however, the maintained temperature T1 is not necessarily limited to be kept constant. As described above, it becomes possible to reduce crystal defects in the sapphire ingot 10 by setting the maintained temperature T1 within the range of 1500° C. or more to less than 1800° C. Accordingly, in the temperature maintaining step P2, as long as the maintained temperature T1 is within the temperature range of 1500° C. or more to less than 1800° C., the maintained temperature T1 may vary up and down within the range.

In this manner, the method for producing the sapphire single crystal to which the present invention is applied can be practiced by being characterized to include: a first step in which an ingot of sapphire single crystal to be subjected to machine processing is mounted in a heating apparatus for heating the ingot of sapphire single crystal; and a second step in which the ingot of sapphire single crystal mounted in the heating apparatus is heated in an atmosphere containing at least one kind selected from a group composed of helium, neon, argon, nitrogen, oxygen, carbon dioxide and carbon monoxide. The sapphire single crystal produced by the producing method can decrease the incidence of cracks in a cutting step afterward, and thereby promising processing methods of sapphire single crystal to be subjected to machine processing.

Further, particularly, in the case of producing an ingot of sapphire single crystal having a large diameter of 4 inches or more, the producing method of sapphire single crystal is capable of stably improving the yield. Moreover, the producing method of sapphire single crystal is extremely effective in producing by pulling c-axis sapphire single crystal having a large diameter of 4 inches.

### REFERENCE SIGNS LIST

2 . . . Heating apparatus
3 . . . Single crystal pulling apparatus
10 . . . Sapphire ingot

1. A method for producing a sapphire single crystal, comprising:
a first step in which an ingot of sapphire single crystal to be subjected to machine processing is mounted in a heating apparatus for heating the ingot of sapphire single crystal; and
a second step in which the ingot of sapphire single crystal mounted in the heating apparatus is heated in an atmosphere containing at least one kind selected from a group composed of helium, neon, argon, nitrogen, oxygen, carbon dioxide and carbon monoxide.

2. The method for producing a sapphire single crystal according to claim 1, wherein the atmosphere in the second step contains at least oxygen.

3. The method for producing a sapphire single crystal according to claim 1, wherein the atmosphere in the second step contains at least oxygen and nitrogen.

4. The method for producing a sapphire single crystal according to claim 2, wherein oxygen concentration of the atmosphere in the second step is equal to or more than oxygen concentration in the air.

5. The method for producing a sapphire single crystal according to claim 2, wherein oxygen concentration of the atmosphere in the second step is equal to or more than 23 volume percent.

6. The method for producing a sapphire single crystal according to claim 1, wherein the atmosphere in the second step is heated to a range of 1500° C. or more to less than 1800° C.

7. The method for producing a sapphire single crystal according to claim 1, wherein the second step is continued for 30 hours or more.

8. The method for producing a sapphire single crystal according to claim 1, wherein, in the first step, the ingot of sapphire single crystal to be subjected to machine processing for obtaining at least two plate-like sapphire single crystals is used.

9. The method for producing a sapphire single crystal according to claim 1, wherein, in the first step, the ingot of sapphire single crystal having been obtained by a pulling method is used.

10. The method for producing a sapphire single crystal according to claim 1, further comprising a third step in which machine processing is applied to the ingot of sapphire single crystal obtained via the second step.

11. A sapphire single crystal produced by the method for producing a sapphire single crystal according to claim 1.
